(19) United States
(12) Patent Application Publication
(10) Pub. No.: US 2025/0126902 A1
(43) Pub. Date: Apr. 17, 2025

(54) PHOTOVOLTAIC MODULES WITH LASER WELDED GLASS

(71) Applicant: Alliance for Sustainable Energy, LLC, Golden, CO (US)

(72) Inventors: David Levi YOUNG, Golden, CO (US); Pauls STRADINS, Golden, CO (US)

(21) Appl. No.: 18/914,943

(22) Filed: Oct. 14, 2024

Related U.S. Application Data
(60) Provisional application No. 63/590,211, filed on Oct. 13, 2023.

(51) Int. Cl. H10F 19/80; H10F 77/00; H10F 77/30; H10F 77/40

(52) U.S. Cl. CPC H10F 19/807; H10F 77/315; H10F 77/407; H10F 77/935

(57) ABSTRACT

Described herein are photovoltaic devices and methods which utilize femtosecond (fs) lasers to create a glass/glass weld, hermetically encapsulating photovoltaic devices that provide both reduced cost and increased cell life and efficiency. For example, glass/glass welds can reduce manufacturing time and costs, increase cell life by removing encapsulant failure which is a leading cause of cell degradation and provide for increased optical properties, which improves cell efficiency.

### CROSS-REFERENCE TO RELATED APPLICATIONS

This application claims priority from U.S. Provisional Patent Application No. 63/590,211, filed on Oct. 13, 2023, the contents of which are incorporated herein by reference in their entirety.

### CONTRACTUAL ORIGIN

This invention was made with government support under Contract No. DE-AC36-08GO28308 awarded by the Department of Energy. The government has certain rights in the invention.

### BACKGROUND

In order to meet the desired $0.02/kWh goal for photovoltaics modules, modules need to improve in efficiency, cost, and durability. Described herein are methods to improve PV modules in all three categories by adding value to the module glass. In order to meet this goal, commercial PV modules need to improve in four areas: 1) decreased manufacturing time—vacuum lamination takes ˜12 min/cycle, which drives the requirements for large production floorspace and high capex (multiple parallel tools) for production throughput; 2) degradation due to polymer-based encapsulates and sealing materials; 3) the need for aluminum frames for mechanical strength and mounting; and 4) poor optical coupling to cells. It can be seen from the foregoing that there is a need in the art for photovoltaic devices and methods designed to improve cost, efficiency and durability.

### SUMMARY

Described herein are photovoltaic devices and methods which utilize femtosecond (fs) lasers to create a glass/glass weld, hermetically encapsulating photovoltaic devices that provide both reduced cost and increased cell life and efficiency. For example, glass/glass welds can reduce manufacturing time and costs, increase cell life by removing encapsulant failure which is a leading cause of cell degradation and provide for increased optical properties, which improves cell efficiency.

The present application described the design of cells and modules together as a synergistic unit, removing unnecessary and known degradation-prone components while utilizing modern industrial laser processing to increase production throughput, step-change sealing technology, and using the glass itself as a mechanical frame. As an example, the provided photovoltaic cells incorporate: 1) A diffused antireflection coating (ARC), applied during glass production cool down, will last as long as the glass. 2) Embossed rolled glass and diffused optical features in the glass refract light around busbars and from the module edges to increase photon flux to the cells. These busbar “cloaking” features allow wider busbars using aluminum or copper rather than silver without current loss and help to position cells within the polymer-free module (no EVA). 3) Focused laser heating allows bending/welding of glass into a robust mechanical shape to eliminate the aluminum frame. 4) Low-cost industrial lasers can be used to weld the two sheets of glass together to form a hermetic seal in a fraction of current lamination time.

In an aspect, provided is a device comprising: a) one or more photovoltaic modules; and b) a first transparent layer and a second transparent layer encapsulating the one or more photovoltaic modules; wherein the first transparent layer and second transparent layer are welded together to form a hermetic seal around the one or more photovoltaic modules.

In an aspect, provided is a method comprising: a) providing one or more photovoltaic modules, a first transparent layer, and a second transparent layer; b) positioning the one or more photovoltaic modules between the first transparent layer and the second transparent layer; and c) welding the first transparent layer and the second transparent layer together using a laser, thereby creating a hermetic seal around the one or more photovoltaic modules and forming a photovoltaic panel.

The term photovoltaic modules is used inclusively, including for example, individual photovoltaic cells or more complex configurations.

The two transparent layers may be separated from the photovoltaic module by a gap to improve thermal operation of the photovoltaic device. For example, the first transparent layer and the photovoltaic module and/or the second transparent layer and the photovoltaic module may be separated by a gap less than or equal to 200 μm, less than or equal to 100 μm or optionally, less than or equal to 50 μm.

The first transparent layer, the second transparent layer may comprise or consist of glass. For example, the glass may comprise rolled glass, i.e., glass created via a roll to roll manufacturing process in order to reduce material costs. The glass may further incorporate additional optical features including, for example, antireflection coating or optical features including ribbed or embossed features.

The hermetic seal may be generated by a fast pulse laser capable of non-linear optical absorption The hermetic seal may be generated via a femtosecond laser, including for example, a femtosecond laser that operates at a pulse frequency of about 200-400 fs, 200-1000 fs, or optionally 400 fs-200 ps. The laser may have a power of about 2-20 W and a frequency of about 200 hz. The laser may provide electromagnetic radiation in the ultraviolet spectrum, for example greater than 800 nm, or about 1030 nm.

The devices and methods described herein may be beneficial in that they do not include a polymer sealant between the transparent layers, which may increase the lifecycle of the photovoltaic device or solar panel. The lifecycle of the device may be greater than or equal to 25 years, 30 years, 50 years, 75 years, 100 years, or optionally, 125 years. The lifecycle of the device or photovoltaic panel may be increased, for example by a factor of 2 times, 3 times, or optionally 5 times.

The device or solar panel may further comprise a welded feedthrough comprising a metal having a thermal expansion coefficient that is about equal to a thermal expansion coefficient of the first or second transparent layer, for example with glass, Kovar or Invar.

The described devices may withstand a static load test greater than or equal to about 5400 Pa, for example, under the IEC 61215 standard. The device may further incorporate the inclusion of busbars comprising aluminum or copper.

### BRIEF DESCRIPTION OF DRAWINGS

Some embodiments are illustrated in referenced figures of the drawings. It is intended that the embodiments and figures disclosed herein are to be considered illustrative rather than limiting.

FIG. 1 provides an exemplary photovoltaic module comprising multiple cells encapsulated by two glass layers welded together.

FIG. 2 provides displacement contours of COMSOL Finite Element model data under 5400 Pa of uniform static load and is a closer view of FIG. 14.

FIG. 3 illustrates the stress intensity along the edge of the module lengthwise and is a closer view of FIG. 14.

FIG. 4 illustrates the stress intensity along the edge of the module widthwise and is a closer view of FIG. 14.

FIG. 5 provides an illustration and image of a glass/glass weld interface.

FIG. 6 provides thermal data of the glass/glass welding process, indicating that the semiconductor remains at room temperature during welding.

FIG. 7 shows an example glass sample welded glass using a Trumpf laser, illustrating optically flat Newton rings and Solite glass welded lines.

FIG. 8 provides an example weld pattern for glass welding and corresponding dimensions. The shown 6 weld seams are continuous 50 μm with 150 μm between the seams.

FIG. 9 provides example COMSOL data of the welds described in FIG. 8.

FIG. 10 illustrates stress intensity factors of the glass/glass welds shown in FIG. 8.

FIGS. 11A-11B provide an optical image of laser weld lines between two glass samples (FIG. 11A) and geometric variables used in Equation 1 in Example 1 (FIG. 11B).

FIGS. 12A-12B shows a glass/glass laser welded sample glued to two metal cylinders for K_{Ic} measurement (FIG. 12A). Also shown is a press to measure tensile force to weld breakage (FIG. 12B).

FIG. 13 shows measured K_{IC} values for welds made with different laser power, number of weld lines and spacing between the weld lines. The horizontal lines show the range of K_{IC} values for typical soda-lime float glass.

FIGS. 14A-14B show the structural mechanics model simulation of a glass/glass module framed, and supported with two crossbar braces (FIG. 14A and arrows in FIG. 14 B) under 5400 Pa of uniform static load. The heat map shows displacement of the module glass sheets (lower right, FIG. 14B). The 2-D schematic of the edge sealing weld orientation, flaw, and J-integral path (top right, FIG. 14B). The 1D plots of the driving force for weld cracking along the edges (top graph, FIG. 14B) and ends (right graph, FIG. 14B) of the module. The two straight lines in the graphs show the average K_{IC} for glass and the best average measured laser welds.

FIG. 15 provides an example schematic drawing of large area fs laser welding system for solar modules.

FIG. 16 provides the thermal impact of an air cavity on the temperature of a laser-welded glass/glass module. The horizontal line shows the temperature of a conventional module encapsulated with EVA instead of an air gap. The removal of EVA yields lower temperatures if the air gap is kept below approximately 100 μm.

FIG. 17 provides an image of the jig used to press two pieces of glass together during the laser welding process.

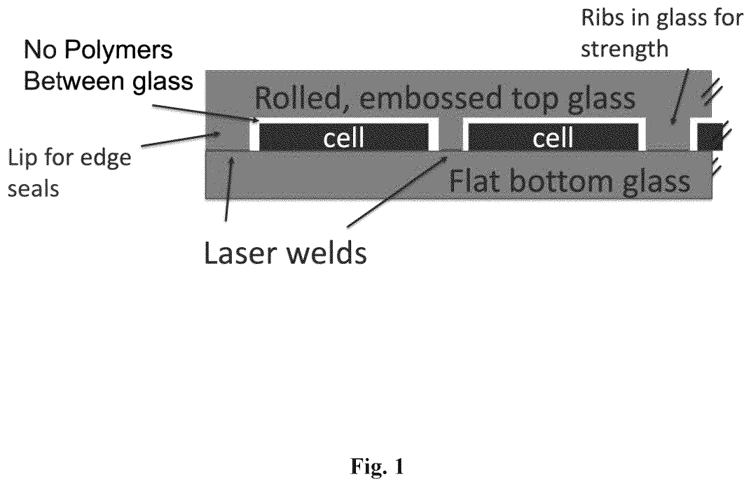

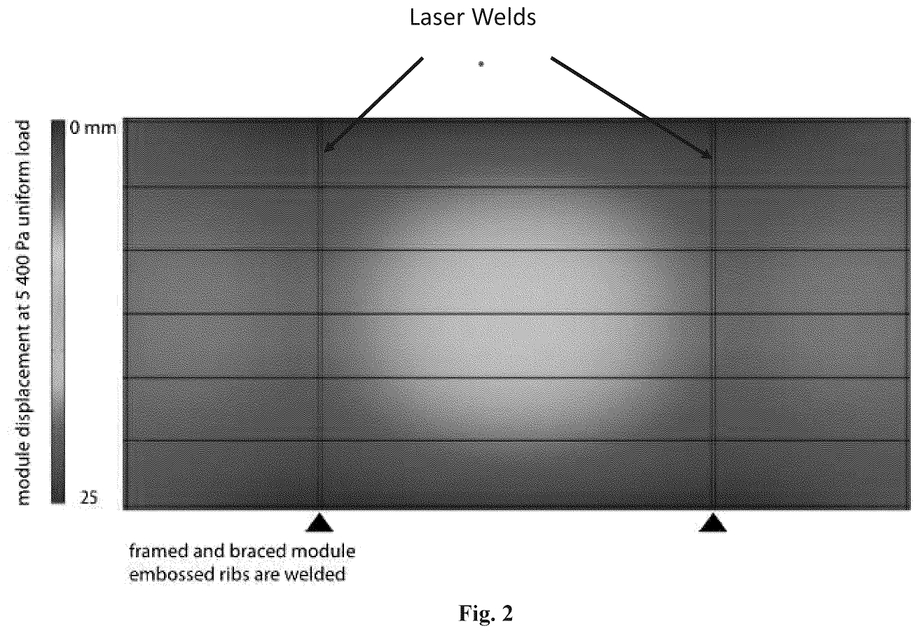

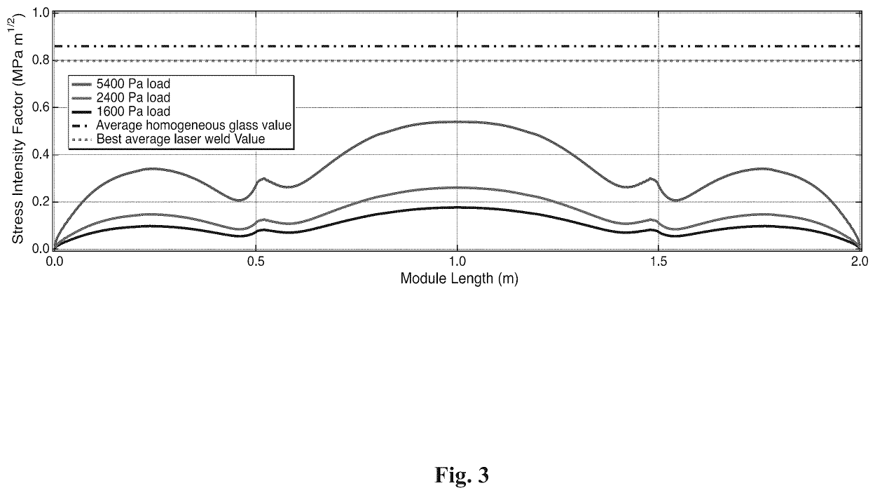

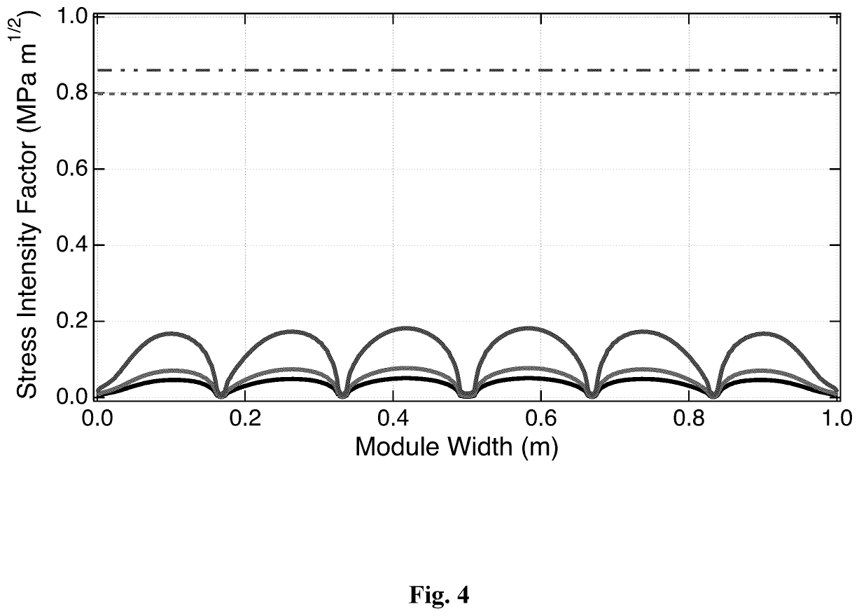

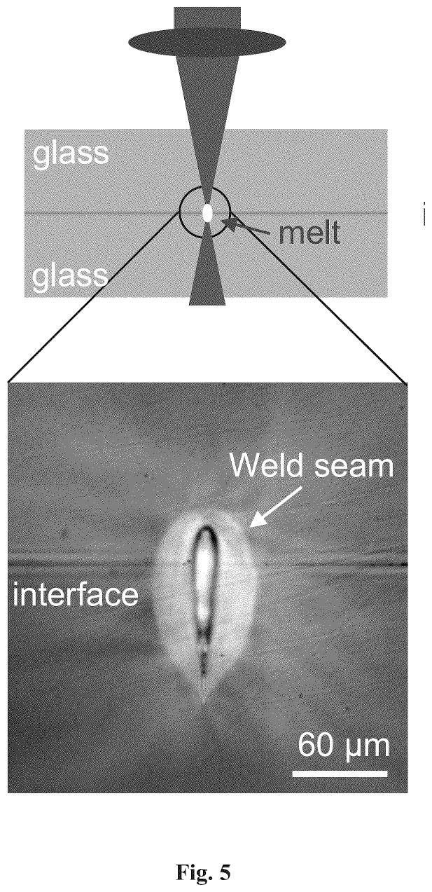

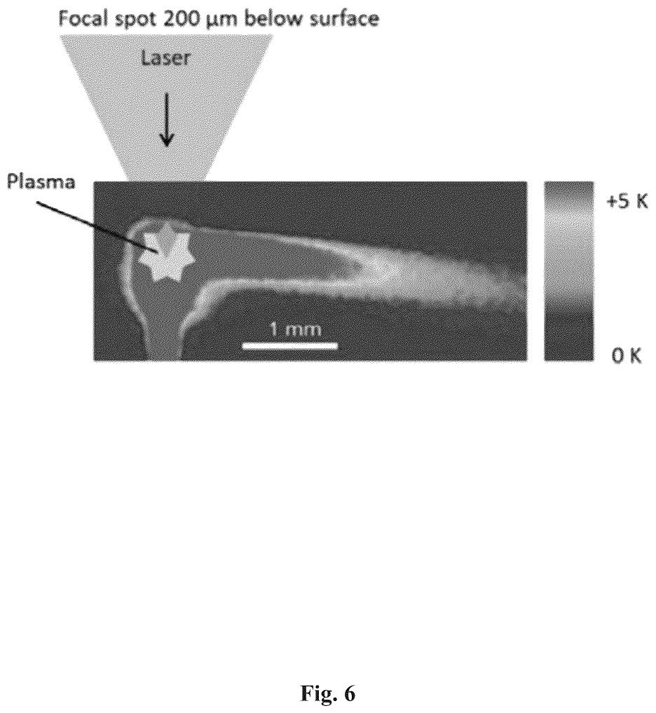

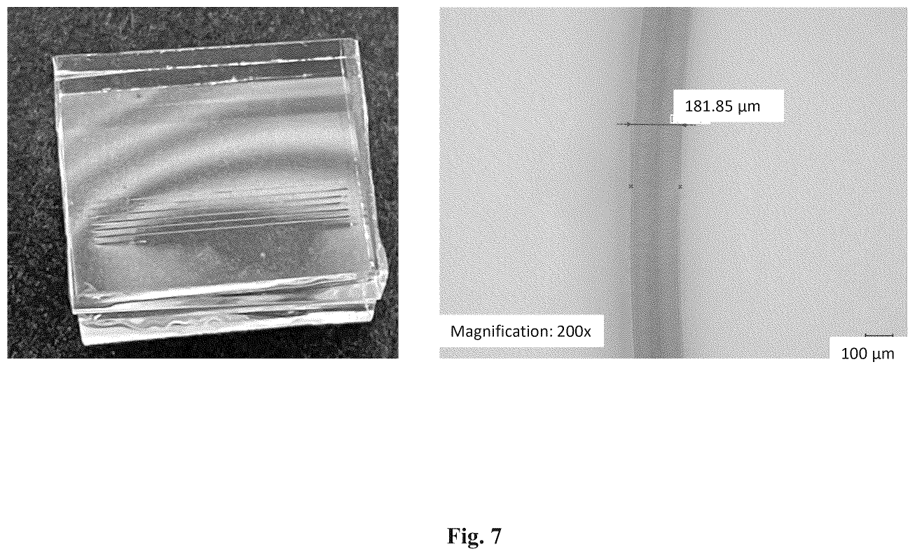

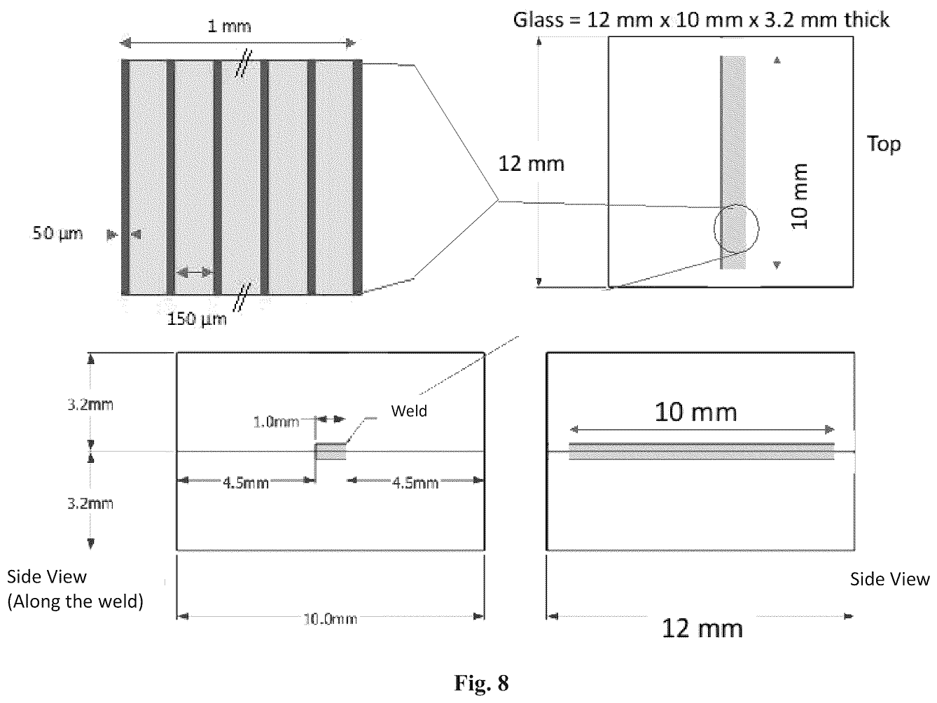

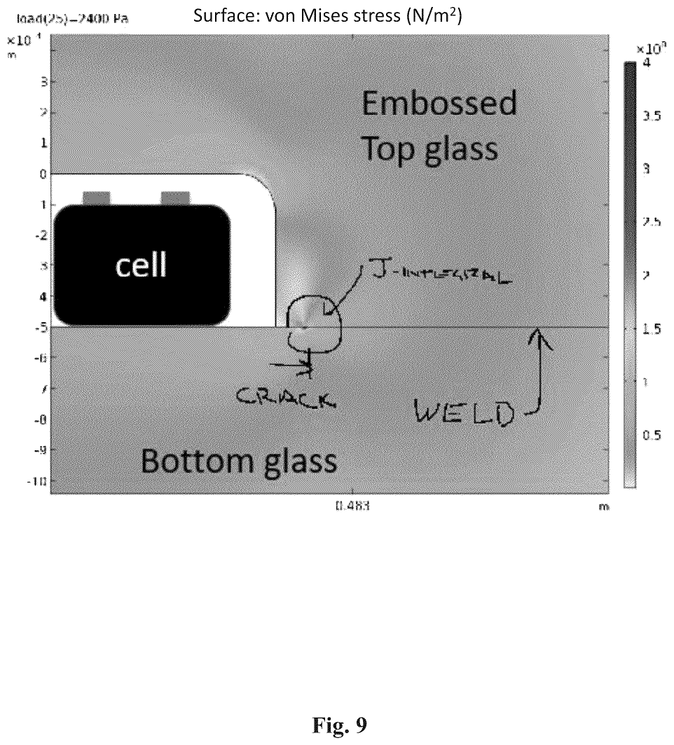

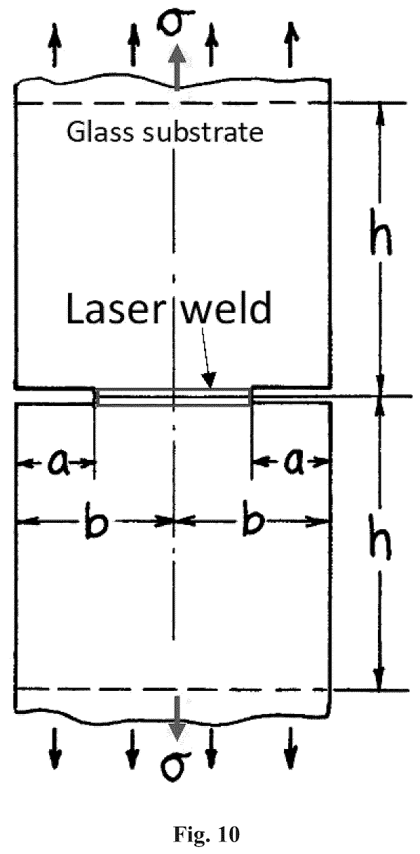

### DETAILED DESCRIPTION

The embodiments described herein should not necessarily be construed as limited to addressing any of the particular problems or deficiencies discussed herein. References in the specification to “one embodiment”, “an embodiment”, “an example embodiment”, “some embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

As used herein the term “substantially” is used to indicate that exact values are not necessarily attainable. By way of example, one of ordinary skill in the art will understand that in some chemical reactions 100% conversion of a reactant is possible, yet unlikely. Most of a reactant may be converted to a product and conversion of the reactant may asymptotically approach 100% conversion. So, although from a practical perspective 100% of the reactant is converted, from a technical perspective, a small and sometimes difficult to define amount remains. For this example of a chemical reactant, that amount may be relatively easily defined by the detection limits of the instrument used to test for it. However, in many cases, this amount may not be easily defined, hence the use of the term “substantially”. In some embodiments of the present invention, the term “substantially” is defined as approaching a specific numeric value or target to within 20%, 15%, 10%, 5%, or within 1% of the value or target. In further embodiments of the present invention, the term “substantially” is defined as approaching a specific numeric value or target to within 1%, 0.9%, 0.8%, 0.7%, 0.6%, 0.5%, 0.4%, 0.3%, 0.2%, or 0.1% of the value or target.

As used herein, the term “about” is used to indicate that exact values are not necessarily attainable. Therefore, the term “about” is used to indicate this uncertainty limit. In some embodiments of the present invention, the term “about” is used to indicate an uncertainty limit of less than or equal to ±20%, ±15%, ±10%, ±5%, or ±1% of a specific numeric value or target. In some embodiments of the present invention, the term “about” is used to indicate an uncertainty limit of less than or equal to ±1%, ±0.9%, ±0.8%, ±0.7%, ±0.6%, ±0.5%, ±0.4%, ±0.3%, ±0.2%, or ±0.1% of a specific numeric value or target.

The provided discussion and examples have been presented for purposes of illustration and description. The foregoing is not intended to limit the aspects, embodiments, or configurations to the form or forms disclosed herein. In the foregoing Detailed Description for example, various features of the aspects, embodiments, or configurations are grouped together in one or more embodiments, configurations, or aspects for the purpose of streamlining the disclosure. The features of the aspects, embodiments, or configurations, may be combined in alternate aspects, embodiments, or configurations other than those discussed above. This method of disclosure is not to be interpreted as reflecting an intention that the aspects, embodiments, or configurations require more features than are expressly recited in each claim. Rather, as the following claims reflect, inventive aspects lie in less than all features of a single foregoing disclosed embodiment, configuration, or aspect. While certain aspects of conventional technology have been discussed to facilitate disclosure of some embodiments of the present invention, the Applicants in no way disclaim these technical aspects, and it is contemplated that the claimed invention may encompass one or more of the conventional technical aspects discussed herein. Thus, the following claims are hereby incorporated into this Detailed Description, with each claim standing on its own as a separate aspect, embodiment, or configuration.

### Example 1—Polymer-Free, Femtosecond Laser Wielded Glass/Glass Solar Modules

Described herein is the use of femto-second (fs) lasers to form glass-to-glass welds for hermetically sealed, polymer-free solar modules. Solite glass coupons were welded together without the use of glass filler using a fs laser with dedicated optics to elongate the focal plane parallel to the incident beam. The resulting welds were then stress tested to failure to reveal the critical stress intensity factor, K_{Ic}. These values were then used in a finite element analysis model of a 1 m by 2 m glass/glass module under a simulated static load test. The results show that the fs laser welds are strong enough for a suitably framed module to pass the IEC 61215 static load test of 5400 Pa. Key to this finding is that the module must be framed and braced, and the glass can be ribbed to allow pockets for the cells and welds inside the border of the module. The result is a module design that is completely polymer-free, hermetically sealed, and easily recycled.

### INTRODUCTION

Many solar module failure mechanisms are tied directly to the use of polymers in the laminated stack. These failures include discoloration, which decreases photon flux to the cells, and delamination which can lead to moisture and oxygen in-diffusion, enabling contact corrosion. Perovskite cells are extremely sensitive to moisture and oxygen, to which polymers are poor barriers. This contribution explores a new module design that eliminates polymer materials and instead forms a glass/glass welded hermetically sealed module using fs laser technology.

Encapsulant between the glass has been omitted in the “NICE” module by Apollon Solar and in work done by Barth et al. from Colorado State University, where only a polyisobutylene (PIB) polymer edge seal was used to join the glass/glass module. However, even the best double pane windows held together by PIB have seal failure after 20-30 years (compared to 100s of years for glass failure). Eliminating EVA (or any polymer) from the module greatly reduces the chances for degradation, including delamination, corrosion, discoloration and potential induced degradation, all related to moisture or ion ingress interacting with encapsulants. Elimination of EVA within the module can also improve the optics of the module.

Edge sealing by laser glass/frit sealing is known and has been tested on soda lime PV glass however these welds are brittle and not strong enough for outdoor module designs. Key to this work is the use of a relatively new glass welding regime using femtosecond (fs) pulsed lasers which allows a strain-free, high-strength, hermetic seal using non-linear absorption of laser photons to produce localized heating at the glass/glass interface. Miyamoto et al. illustrated these material science concepts well. For IR continuous wave (CW) or nanosecond (ns) lasers the light is absorbed at the surface of the glass (weld), but the free surface allows shrinkage stress to generate cracks in the glass during cool down leaving the weld region under tensile stress. This type of welding is only appropriate for glass with a low coefficient of thermal expansion (CTE), like quartz. However, if femto-second pulses are used the more intense photon flux allows non-linear absorption of the energy at the focal point near the interface of the two glass surfaces. This allows a stress-free weld to be formed without a free surface because the isotropic pressure on the molten glass does not allow the glass to plastically deform. Thus, the use of fs lasers for stress-free welds is vital to forming strong, durable welds and is a differentiator from the previous work.

The present application demonstrates using glass/glass fs laser welding without filler to seal glass/glass photovoltaic modules. This includes forming the fs laser welds between two solar glass pieces and performing a controlled break of the weld to measure the critical stress intensity factor of the weld. Additionally, included is a structural mechanics study of the simulated laser-welded, glass/glass module under static load conditions. The model measured the stress intensity factors over the area 1 m×2 m module. We found that, with a slight redesign of the module (embossed glass features, bracing of the glass), the stress intensity factors at the weld lines do not exceed the measured critical stress intensity factor even under the maximum load of 5400 Pa. Finally, thermal-optical analysis of the laser-welded module indicates that its operational temperature will be within a couple of degrees of that of a conventionally encapsulated module if the gas cavity in the laser-welded module is kept under 250 μm in thickness, with thermal benefits seen for air gaps under 100 μm.

### Experiment: Glass/Glass FS Laser Wielding

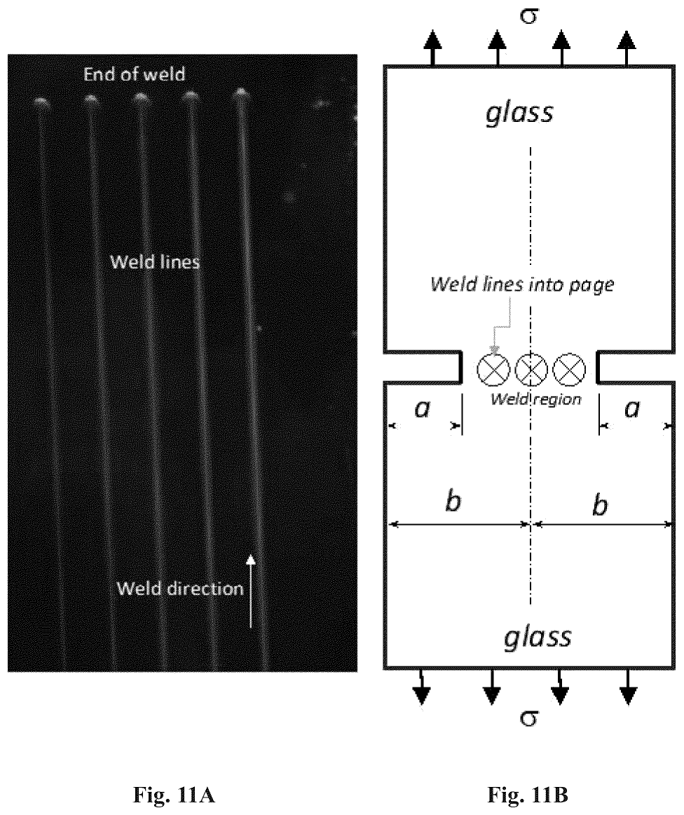

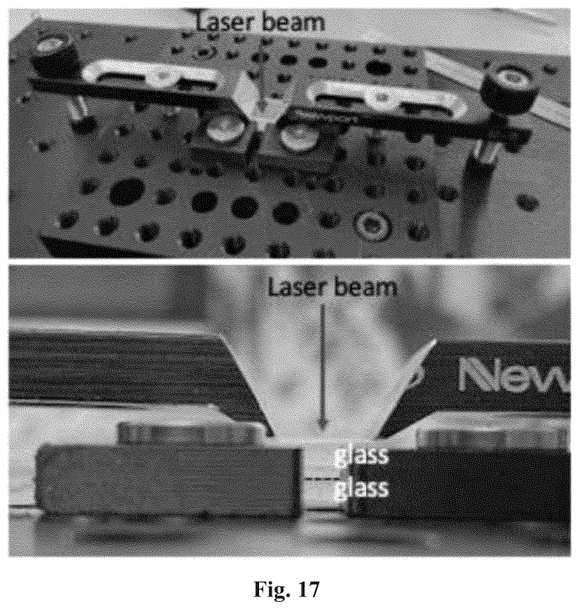

Low-iron, non-textured solar glass samples 3 mm thick were cut to 10 mm by 12 mm and the edges were ground to remove edge cracks. The samples were cleaned and mounted onto an optical bench using a jig to press two samples together. A 20 W fs laser (TruMicro 2030—TRUMPF Lasers) of wavelength 1030 nm equipped with edge cracks. The samples were cleaned and mounted onto an optical bench using a jig to press two samples together, as shown in FIG. 17. A 20 W fs laser (TruMicro 2030—TRUMPF Lasers) of wavelength 1030 nm equipped with TOPWELD optics was used to weld the glass pieces together. Five to six laser weld lines were formed parallel to the long edge of the glass separated by 70-200 μm as shown in FIG. 11A. Laser power was varied between 12.0% to 13.5% of maximum.

### Experiment: Critical Stress Intensity Factor, K_{ic}

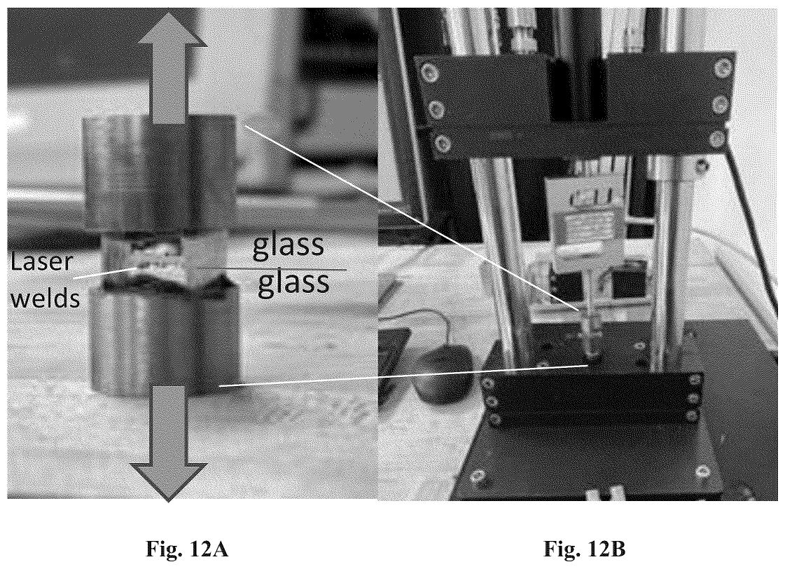

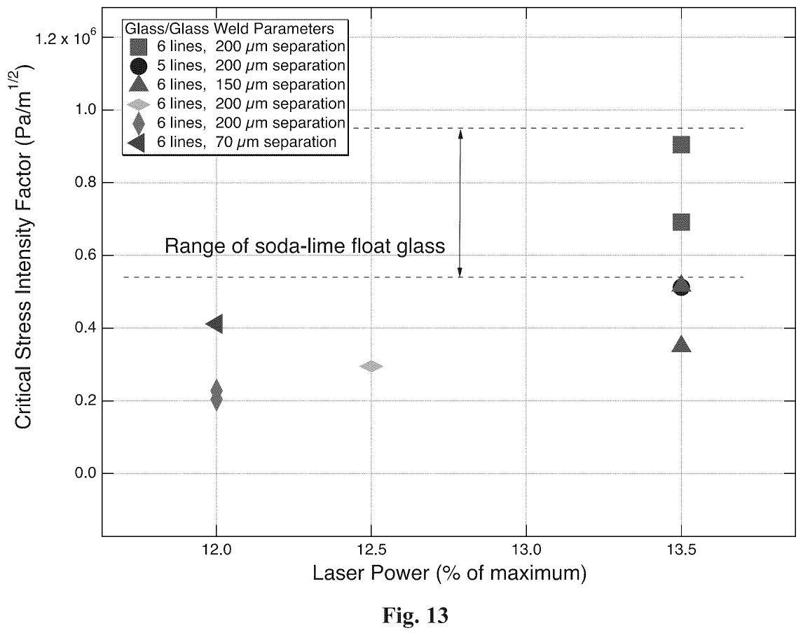

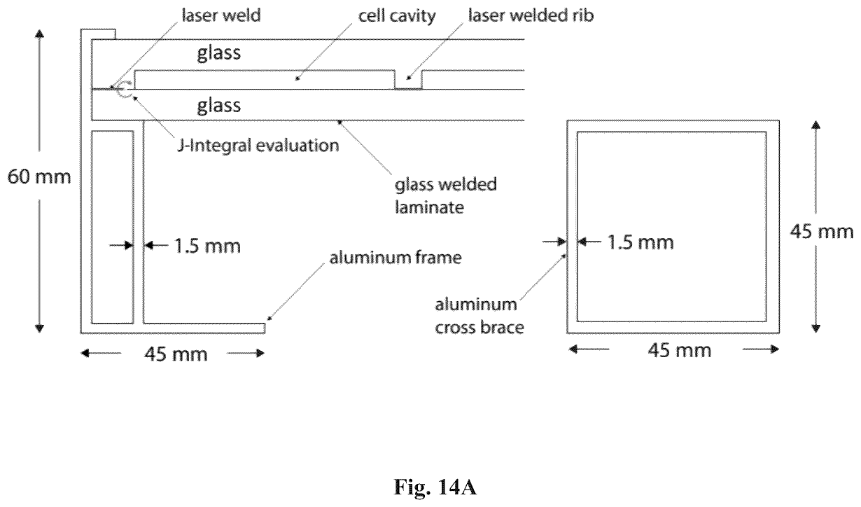

Welded samples were glued to metal cylinders on the flat sides of the glass samples as shown in FIG. 12A. These cylinders attached to a mechanical force test stand that applied a tensile force perpendicular to the weld lines as shown in FIG. 12B. The test measured the maximum force needed to break the weld lines and separate the two glass samples. Equation 1 was used to calculate K_{Ic} of the weld,

$${K}_{IC} = σ \sqrt{π a} F ( a / b ) \qquad ( Eqn . 1 )$$

$$where$$

$$F ( \frac{a}{b} ) = \frac{1.122 - 0.561 ( \frac{a}{b} ) - 0.015 {( \frac{a}{b} )}^{2} + 0.091 {( \frac{a}{b} )}^{3}}{\sqrt{1 - \frac{a}{b}}} \qquad ( Eqn . 2 )$$

where σ is the remote stress on the weld and a and b are geometric lengths defined in FIG. 11B. The function F(a/b) is defined in Benthem et al. and ranges from 2.1-3.4 for our samples. FIG. 13 is a graph of measured K_{IC} values for different weld parameters (number of weld lines, spacing between weld lines and percent of total laser power). The two dashed horizontal lines on the graph show the range of K_{IC} values for typical soda-lime float glass. The graph indicates that laser power plays a major role in how tough the glass/glass weld can be. For our limited number of samples, the higher 13.5% laser power gave higher values than most of the lower power welds. However, the number of weld lines and the spacing between the lines seems to also play a smaller role in determining the K_{IC} value. More work is needed to optimize the weld parameters, but the data of FIG. 13 suggest that some of the welds are near the K_{IC} values of homogeneous glass.

### Modeling: Full-Sized Glass-Welded Module

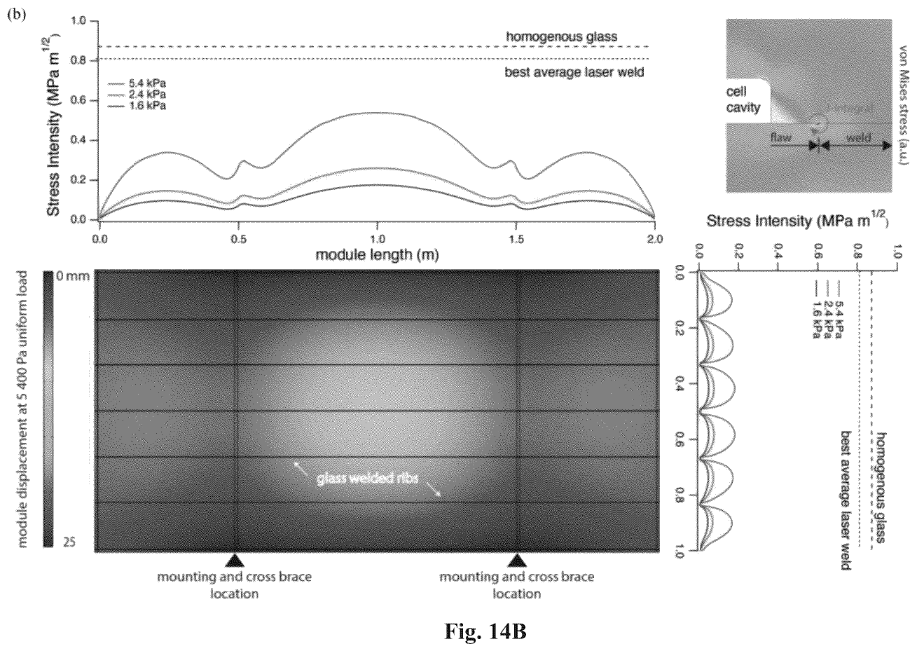

To place the measured K_{IC} values in context to a laser welded module we developed a structural mechanics model of a 1 m×2 m glass/glass laser welded module with no polymer laminate materials between the glass sheets. In order to make space for a typical silicon cell and the associated interconnects we assumed the glass sheets were made by a rolling process with embossed indentations (see schematic in FIG. 14A). These indentations are approximately 200 μm deep to provide space for the thickness of the wafer (˜130-150 μm) plus multi-busbar wires (˜20 μm thick) on both sides of the cell. This embossed depth is consistent with allowable embossed aspect ratio features of less than 20% of the thickness of the glass. The model allowed us to vary the embossed features which included “ribs” in the glass parallel to the long edge of the module. FIG. 14A shows a schematic of the embossed glass with “pockets” for the cells, and flat regions on the edges and on top of the ribs that allow the two sheets of glass to touch for laser welding.

As with most large modules, a frame and two cross braces are needed to minimize the amount of deflection in the module. We modeled an extruded aluminum L-shaped frame with a small box section and cross braces with a box cross section directly supported the glass sheets. The frame and cross braces are attached to the glass module with a thin layer of silicone and the frame is constrained for out-of-plane development at the module mounting points, roughly a quarter of the module's total length from its ends (see FIG. 14B).

The model then simulated a uniform static load over the surface of the module and calculated the out-of-plane displacement of the module and the driving force for weld cracking, J-integral, at an intentionally placed flaw along the weld direction (see FIG. 14B). Considering glass is a linear elastic material

$$J = \frac{{K}_{I}^{2}}{{E}^{′}} + \frac{{K}_{II}^{2}}{{E}^{′}} + \frac{{K}_{III}^{2}}{2 μ} \qquad ( Eqn . 3 )$$

where K_{I}, K_{II}, and K_{III} are the three modes of cracking opening, E′ denotes the plane strain Young's modulus, and μ is the shear modulus.

Since K_{I} is the most pertinent mode to crack propagation in glass, it is, therefore, considered conservatively as the only contribution in the analysis.

The heat map in FIG. 14B shows the deflection of the glass/glass module in the static load test of IEC 61215, at a test load of 5400 Pa. The K_{I} values evaluated at the inner interface of the welds running lengthwise (FIG. 14B, top graph) and widthwise (FIG. 14B, right graph) are presented in FIG. 14B and represent the region of the high driving force for cracks in the welds under simulated static load conditions. These plots show, for three different loads, that the K_{I} values are near zero on the edges, rise and then fall to the point under the frame brace (arrows in FIG. 14B) and then rise to their maximum at the center of the module. The K_{I} values are symmetric from 0-1 m and 1-2 m. The same type of information for the width of the module is shown in the right graph, but here the K_{I} values are much lower and are periodic between the edge of the module and at each welded rib. For reference, we plot the average K_{IC} value of glass and the average K_{IC} value of the best two laser weld results from this example on the two graphs.

### DISCUSSION

A takeaway from the graphs in FIGS. 14A-14B is that the K_{I} of the glass under the three loads is less than the K_{IC} of the glass/glass fs laser welds. This implies that the fs laser welded glass/glass module with a suitably stiff frame will survive the IEC 61215 5400 Pa static load test. The multiple welded ribs running lengthwise help to limit the deflection and hence the K_{I} in the right graph (well below K_{IC} of glass and the laser welds), but the top graph shows that welded widthwise ribs and/or stiffer support should be used to increase the safety factor of this module design.

This example shows that glass/glass fs laser welding is tough enough to withstand the stress in a solar module under static load testing, provided adequate framing and bracing are provided in the mounting structure. Optimization of the laser welding parameters and embossed glass features should be done before load tests are either further simulated or experimentally measured. However, given the nature of the glass/glass welds, the module should be made as stiff as possible to avoid excessive displacement under load.

The excellent measured K_{IC} values of the laser welds indicate that the gap between glass samples during welding was smaller than 10 μm as this is the known maximum gap to support glass/glass welding. This observation is also consistent with typical micron-scale roughness of non-textured rolled glass used for this experiment and in modules.

This study was designed to only test the K_{IC} of fs laser welds on solar glass and to simulate a module static load test to see if the welds were tough enough to survive. We may conclude that they are. This example also addresses three other concerns for the new all glass module: 1) electrical feedthroughs; 2) scaling the welding process to industrial lines; and 3) heating effects of a glass/glass, polymer-free module.

Electrical feedthroughs are an important part of any module design because they provide electrical access to the semiconductor device to the outside circuit while trying to prevent exchange of the atmosphere into the module. Typical modules use polymers to seal electrical feedthroughs, but our goal is to remove polymers from the module and provide a hermetically sealed product. Fs laser welding enables hermetically sealed glass-to-metal welds and has been demonstrated as a fabrication path to fuse glass protective endcaps onto metal sleeves for optical fibers. Glass-to-titanium welds have been qualified for medical implant devices, but thermal expansion mismatch between most metals and glass will likely cause cracking during thermal cycling of outdoor PV modules. However, metal alloys like Kovar and Invar, with matched thermal expansion coefficients to glass, may provide a route to develop a rugged glass-to-metal hermetically sealed feedthrough for PV modules. An existence proof for this idea is well known in the scientific vacuum industry where hot-cathode ion-gauges have metal/glass feedthroughs with allowable bakeout temperatures exceeding 400° C.

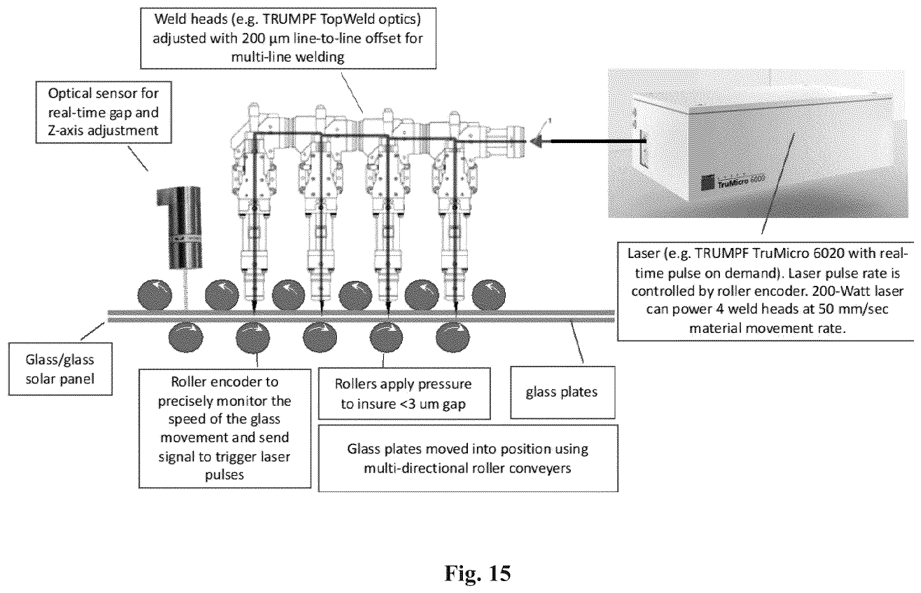

FIG. 15 shows a concept schematic for an industrial tool to laser weld solar modules. The tool has a single laser that powers multiple laser weld heads mounted over the glass/glass module. The glass sheets are moved under the heads between 10-50 mm/s and are pressed together by top and bottom rollers to ensure a gap of <3 μm between the sheets. In FIG. 15 an optical sensor is used to monitor the gap and z-axis of the glass/glass interface to provide real-time feedback adjustment to the focal plane of the lasers. This will account for natural variations in the glass thickness and provide feedback on weld quality. Using this tool as a proxy for an industrial fs laser welding system we can make some rough comparisons to the traditional lamination process to estimate if the welding process is feasible for high-throughput, low-cost module manufacturing. Heating: For traditional lamination, the entire module needs to be heated to about 135° C. and held there for the laminate to cure and then cool to room temperature. For the fs laser welding process only local heating at the weld site is needed while the rest of the module (within a few mm of the weld) remains at room temperature. Throughput: A typical lamination process requires pressing and curing times of approximately 15-21 mins. The laser welding tool illustrated in FIG. 15 has a maximum weld speed of 5 cm/sec which translates to 5.3 mins to weld the module design shown in FIG. 14. Cost: A small 1 m×2 m laminator costs about $70,000, uses 2-3 laminate layers per module and consumes about 27 kW while operating. A tool this size would have a throughput of one module every 20 mins. Larger laminators exist and may have better economies of scale. The laser welding tool shown in FIG. 15 is estimated to cost about $550,000, has no material inputs, and uses about 7 kW in operation and could weld about four modules in 21 mins.

Finally, the removal of polymer laminates from a PV module may have beneficial thermal effects that could translate to decreased proper degradation rates and reductions in the levelized costs of electricity (LCOE) if the gas cavity that replaces the laminate encapsulant is kept below approximately 100 μm in thickness. Encapsulants, such as EVA, absorb infrared light within silicon modules. Thus, the elimination of absorption that occurs in encapsulants would yield reduced heat generation and module temperatures. In addition to lower heat generation, the switch from encapsulant to a gas cavity would also change the thermal resistance between the photovoltaic cell and the front module glass. That change can either reduce or increase the temperature of the cell material depending on whether the thermal resistance of the gas cavity is greater or smaller than the encapsulant layer. The combined impact of the module absorption and thermal resistance is considered by applying a heat-flow framework and an optical-thermal module, then numerically solving a system of equations among the cell, front glass, and rear glass temperatures.

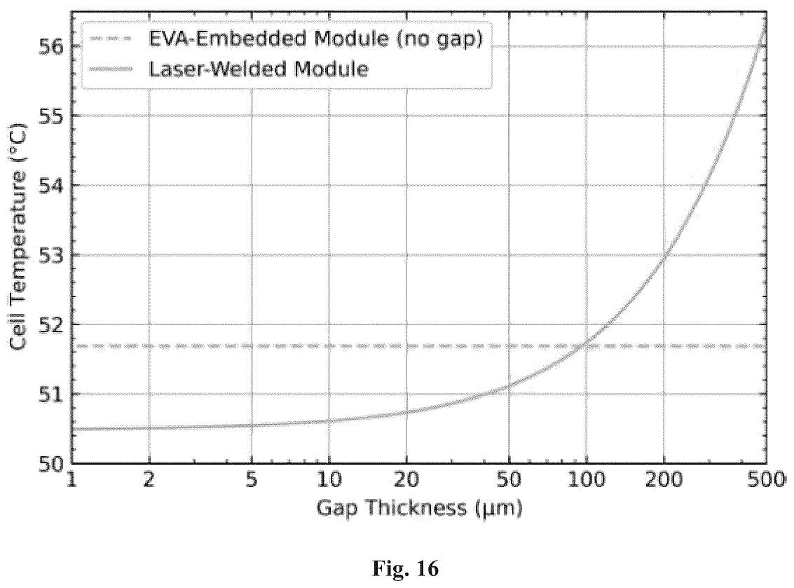

The temperature of the cell within a laser-welded module depends importantly on the thickness of the gas cavity, as shown in FIG. 16. These simulations were done for a selective-emitter passivated emitter rear contact cell (PERC) with 24% efficiency under 1 sun, 25° C. ambient, 1 m/s wind speed, and open rack conditions. The module architecture is glass/glass with symmetric air gaps between the ell and the front and rear glass. The thermal conductivity is taken as 0.028 W m⁻¹ K⁻¹ for air compared with 0.23 W m⁻¹ K⁻¹ for EVA. It is seen that the laser-welded module has a thermal advantage or disadvantage depending on the gap thickness. For a gap thickness of 5 μm or less, the cell temperature within the laser-welded module is 1.2° C. lower than that of a corresponding EVA-embedded module, a change due equally to the removal of absorption and thermal resistance across the EVA layer. At around 100 μm of gap thickness, the net temperature difference becomes zero as the increases in thermal resistance negates the impact of reduce heat generation in the module. The cell temperature increases at thicker air gaps, leading to a 1.3° C. higher temperature than the EVA-embedded module for an air gap thickness of 200 μm. While 200 μm has been shown to be an optimal diameter for wires multiwire busbar configurations based on the consideration of shading and electrical resistance alone, thinner wire diameters offer lower cell breakage, altogether implying that the practical gap thickness for a laser-welded module is less than or equal to 200 μm. Additionally, the presence of busbars in the air gap could improve the thermal conductance of the air gap, an effect that was not considered in this example.

In summary, the temperature of a laser-welded module is expected to be within 2° C. of the temperature of conventional modules, resulting in a thermal benefit if the wire diameter and gas cavity thickness can be reduced below about 100 μm. The thermal benefit seen with the thinnest air gaps relates to a 0.6° C. change in annual irradiance-weighted temperatures, which is expected to lower LCOE by an amount equivalent to that of a 0.1%-0.2% increase in absolute standard temperature conditions (STC) efficiency because of the dependence of operating efficiency and module lifespan on temperature. Furthermore, the thermal benefits of a laser-welded module would become greater for cells with lower optical heat generation (such as passivated emitter and rear totally diffused cells (PERT) cells), thus offer advanced heat mitigation in photovoltaics.

### CONCLUSION

Described herein, by experimentation and modeling, is a polymer-free, glass/glass fs laser welded module will pass the IEC 61215 static load test at a test load of 5400 Pa. The module design requires embossed indentations and ribs in the glass to allow cells and interconnects to be routed properly and to increase the stiffness of the module, respectively. These results are promising for a revolutionary change in module design that provides hermetic edge sealing and polymer-free construction to reduce degradation modes, operation temperature, cost, and straight forward recycling by simply breaking the glass to remove the cells and the metal interconnects.

The terms and expressions which have been employed herein are used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments, exemplary embodiments and optional features, modification and variation of the concepts herein disclosed may be resorted to by those skilled in the art, and that such modifications and variations are considered to be within the scope of this invention as defined by the appended claims. The specific embodiments provided herein are examples of useful embodiments of the present invention and it will be apparent to one skilled in the art that the present invention may be carried out using a large number of variations of the devices, device components, methods steps set forth in the present description. As will be obvious to one of skill in the art, methods and devices useful for the present methods can include a large number of optional composition and processing elements and steps.

As used herein and in the appended claims, the singular forms “a”, “an”, and “the” include plural reference unless the context clearly dictates otherwise. Thus, for example, reference to “a cell” includes a plurality of such cells and equivalents thereof known to those skilled in the art. As well, the terms “a” (or “an”), “one or more” and “at least one” can be used interchangeably herein. It is also to be noted that the terms “comprising”, “including”, and “having” can be used interchangeably. The expression “of any of claims XX-YY” (wherein XX and YY refer to claim numbers) is intended to provide a multiple dependent claim in the alternative form, and in some embodiments is interchangeable with the expression “as in any one of claims XX-YY.”

When a group of substituents is disclosed herein, it is understood that all individual members of that group and all subgroups, are disclosed separately. When a Markush group or other grouping is used herein, all individual members of the group and all combinations and subcombinations possible of the group are intended to be individually included in the disclosure. For example, when a device is set forth disclosing a range of materials, device components, and/or device configurations, the description is intended to include specific reference of each combination and/or variation corresponding to the disclosed range.

Every formulation or combination of components described or exemplified herein can be used to practice the invention, unless otherwise stated.

Whenever a range is given in the specification, for example, a density range, a number range, a temperature range, a time range, or a composition or concentration range, all intermediate ranges and subranges, as well as all individual values included in the ranges given are intended to be included in the disclosure. It will be understood that any subranges or individual values in a range or subrange that are included in the description herein can be excluded from the claims herein.

All patents and publications mentioned in the specification are indicative of the levels of skill of those skilled in the art to which the invention pertains. References cited herein are incorporated by reference herein in their entirety to indicate the state of the art as of their publication or filing date and it is intended that this information can be employed herein, if needed, to exclude specific embodiments that are in the prior art. For example, when composition of matter is claimed, it should be understood that compounds known and available in the art prior to Applicant's invention, including compounds for which an enabling disclosure is provided in the references cited herein, are not intended to be included in the composition of matter claims herein.

As used herein, “comprising” is synonymous with “including,” “containing,” or “characterized by,” and is inclusive or open-ended and does not exclude additional, unrecited elements or method steps. As used herein, “consisting of” excludes any element, step, or ingredient not specified in the claim element. As used herein, “consisting essentially of” does not exclude materials or steps that do not materially affect the basic and novel characteristics of the claim. In each instance herein any of the terms “comprising”, “consisting essentially of” and “consisting of” may be replaced with either of the other two terms. The invention illustratively described herein suitably may be practiced in the absence of any element or elements, limitation or limitations which is not specifically disclosed herein.

All art-known functional equivalents, of any such materials and methods are intended to be included in this invention. The terms and expressions which have been employed are used as terms of description and not of limitation, and there is no intention that in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the concepts herein disclosed may be resorted to by those skilled in the art, and that such modifications and variations are considered to be within the scope of this invention as defined by the appended claims.

What is claimed is:

1. A device comprising:
one or more photovoltaic modules; and
a first transparent layer and a second transparent layer encapsulating the one or more photovoltaic modules;
wherein the first transparent layer and second transparent layer are welded together to form a hermetic seal around the one or more photovoltaic modules.

2. The device of claim 1, wherein the first transparent layer, the second transparent layer or both comprise glass.

3. The device of claim 2, wherein the glass is rolled glass.

4. The device of claim 1, wherein the hermetic seal is formed using a fast pulse laser capable of non-linear optical absorption.

5. The device of claim 1, wherein the first transparent layer, the second transparent layer or both comprise a diffused antireflection coating.

6. The device of claim 1, wherein the first transparent layer, the second transparent layer or both comprise ribbed or embossed optical features.

7. The device of claim 1, wherein the device does not comprise a polymer sealant between the first transparent layer and the second transparent layer.

8. The device of claim 1, wherein the device lifecycle is greater than or equal to 30 years.

9. The device of claim 1, further comprising a welded feedthrough comprising a metal having a thermal expansion coefficient that is about equal to a thermal expansion coefficient of the first or second transparent layer.

10. The device of claim 1, wherein the first transparent layer and the one or more photovoltaic modules or the second transparent layer and the one or more photovoltaic modules are separated by a gap less than or equal to 200 μm.

11. A method comprising:
providing one or more photovoltaic modules, a first transparent layer, and a second transparent layer;
positioning the one or more photovoltaic modules between the first transparent layer and the second transparent layer; and
welding the first transparent layer and the second transparent layer together using a laser, thereby creating a hermetic seal around the one or more photovoltaic modules and forming a photovoltaic panel.

12. The method of claim 11, wherein the first transparent layer, the second transparent layer or both comprise glass.

13. The method of claim 12, wherein the glass is rolled glass.

14. The method of claim 11, wherein the laser is a fast pulse laser capable of non-linear optical absorption.

15. The method of claim 11, wherein the first transparent layer, the second transparent layer or both comprise a diffused antireflection coating.

16. The method of claim 11, wherein the first transparent layer, the second transparent layer or both comprise ribbed or embossed optical features.

17. The method of claim 11, wherein the photovoltaic panel does not comprise a polymer sealant between the first transparent layer and the second transparent layer.

18. The method of claim 11, wherein the photovoltaic panel has a lifecycle is greater than or equal to 30 years.

19. The method of claim 11, further comprising providing a welded feedthrough comprising a metal having a thermal expansion coefficient that is about equal to a thermal expansion coefficient of the first or second transparent layer.

20. The method of claim 11, wherein the first transparent layer and the one or more photovoltaic modules or the second transparent layer and the one or more photovoltaic modules are separated by a gap less than or equal to 200 μm.
